(19) United States
(12) Patent Application Publication
(10) Pub. No.: US 2025/0079897 A1
(43) Pub. Date: Mar. 6, 2025

(54) WIRELESS POWER ON PRODUCTION LINE

(71) Applicant: Toyota Boshoku America, Inc., Novi, MI (US)

(72) Inventors: Kidus Tesfamariam, Waterloo (CA); Amr Shokry, LaSalle (CA)

(21) Appl. No.: 18/821,388

(22) Filed: Aug. 30, 2024

Related U.S. Application Data
(60) Provisional application No. 63/536,380, filed on Sep. 1, 2023.

(51) Int. Cl. H02J 50/12; H02J 50/80; H02J 50/90; H04B 5/48

(52) U.S. Cl. CPC H02J 50/12; H02J 50/80; H02J 50/90; H04B 5/48

(57) ABSTRACT

A wireless power system of a testing system, the wireless power system including a transmitter associated with an assembly rail and a receiver associated with a component. The transmitter transfers wireless power to the receiver.

### CROSS-REFERENCE TO RELATED APPLICATIONS

This application claims the benefit of Provisional U.S. Patent Application Ser. No. 63/544,380 filed Sep. 1, 2023, the disclosure of which is incorporated by reference in its entirety herein.

### BACKGROUND

During manufacturing, workers on an assembly line manually perform certain tasks. For example, some components on the assembly line might need to be tested during production. This requires that a worker manually connect and disconnect a power source to the component for the test.

### SUMMARY

A wireless power system of a testing system, the wireless power system including a transmitter associated with an assembly rail and a receiver associated with a component. The transmitter transfers wireless power to the receiver.

In one example wireless power system of a testing system, a pallet is connected to the component, and the pallet moves relative to the assembly rail.

In one example wireless power system of a testing system, the system includes a power source that supplies power to the transmitter, and the transmitter sends a wireless power signal to the receiver to wirelessly power the component during a test.

In one example wireless power system of a testing system, one of electromagnetic resonance or induction is used to wirelessly transfer power from the transmitter to the receiver.

In one example wireless power system of a testing system, the receiver is connected to the pallet by a first attachment mechanism, and the transmitter is connected to the assembly rail by a second attachment mechanism.

In one example wireless power system of a testing system, the first attachment mechanism and the second attachment mechanism are each a threaded fastener or a screw.

In one example wireless power system of a testing system, a connector connects the component to the receiver, and power travels from the receiver, through the connector, and to the component for testing.

In one example wireless power system of a testing system, the system includes a controller, a display associated with the controller, and a communication module. Data obtained during a test is wirelessly transferred through a two-way wireless signal between the communication module and the controller and shown on the display.

In one example wireless power system of a testing system, the communication module is associated with the pallet, and a wireless data communication transceiver located between the control and the communication module wirelessly transfers the data between the controller and the communication module.

In one example wireless power system of a testing system, the controller sends a signal to the transmitter through a wired line to control one-way transfer of wireless power from the transmitter to the receiver during testing.

In one example wireless power system of a testing system, the system includes a motor, a conveyor belt moved by the motor, a connection station, a testing station, and a disconnection station. The pallet with the component attached to the pallet moves along the production line from the connection station, to the testing station, to the disconnection station along the conveyor belt.

In one example wireless power system of a testing system, the system including a master computer, and the testing station comprises a plurality of testing stations each including a controller, a sensor, and a display. When each of the sensors detect the pallet at one of the plurality of testing stations, a signal is sent to the master computer to send a signal to the motor to stop the conveyor belt so that a test can be performed. The controller sends a signal to the transmitter to begin the transfer of wireless power to from the transmitter to the receiver to power the test.

In one example wireless power system of a testing system, data obtained from the test at the testing station is communicated to the master computer and the controller and shown on the display, and the master computer sends a signal to the transmitter to stop the transmission of wireless power to the receiver when the test is complete.

In one example wireless power system of a testing system, if the component passes the test, the master computer sends a signal to the motor to move the conveyor belt so that the pallet leaves the testing station.

In one example wireless power system of a testing system, once when testing is completed at the testing station, the master computer sends a signal to the motor to move the conveyor belt so that the pallet leaves the testing station and moves to the disconnection station where the component is disconnected from the pallet.

### BRIEF DESCRIPTION OF THE DRAWINGS

FIG. 1 shows a component at a testing station on a production line; and

FIG. 2 shows stations along the production line.

### DETAILED DESCRIPTION

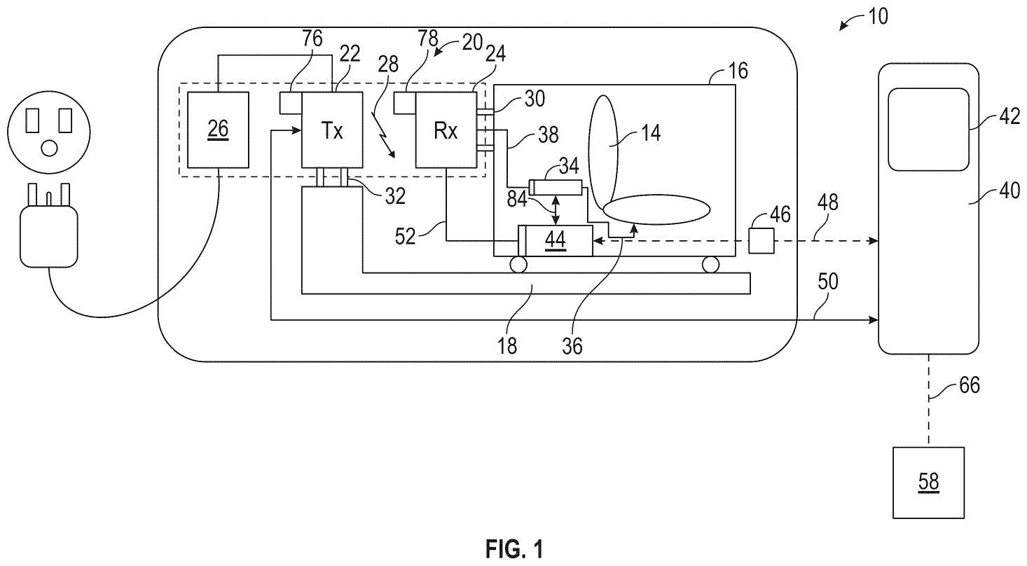

FIG. 1 shows a testing station 10 at an end of a production line 12. A component 14 is connected to a pallet 16. In one example, the component 14 is a vehicle seat. Although a vehicle seat is illustrated and described below, other types of components 14 can be tested on the production line 12.

The pallet 16 moves relative to an assembly rail 18. A wireless power system 20 includes a transmitter 22 and a receiver 24. The transmitter 22 is associated with the assembly rail 18, and the receiver 24 is associated with the pallet 16. A power source 26 supplies power to the transmitter 22, and the transmitter 22 sends a wireless power signal 28 to the receiver 24 to wirelessly power the component 14 during testing. In one example, the power source 26 is an AC-DC charger.

In one example, electromagnetic resonance is used to transfer power from the transmitter 22 to the receiver 24. In another example, induction is used to transfer power from the transmitter 22 to the receiver 24.

The receiver 24 is connected to the pallet 16 by an attachment mechanism 30, and the transmitter 22 is connected to the assembly rail 18 by an attachment mechanism 32. In one example, the attachment mechanisms 30 and 32 are each a threaded fastener or a screw. A connector 34 connects the component 14 to the receiver 24 and collects and stores data collected from the tests performed on the component 14. A wired line 36 connects the component 14 to the connector 34, and a wired line 38 connects the connector 34 to the receiver 24. Power travels from the receiver 24, through the connector 34, and to the component 14 through the wired lines 36 and 38, respectively, for testing.

The testing station 10 also includes a controller 40 and a display 42 associated with the controller 40. In one example, the controller 40 is a programmable logic controller (PLC). In one example, the display 42 is on the controller. The display 42 shows data obtained during testing.

A communication module 44 is associated with the pallet 16. There is communication between the connector 34 and the communication module 44 in both directions through a signal 84. In one example, a signal is sent to provide data collected from the tests from the connector 34 to the communication module 44.

A wireless data communication transceiver 46 is used to wirelessly transfer any data or testing data between the controller 40 and the communication module 44 and is located therebetween. The wireless data communication transceiver 46 wirelessly transfers data through a two-way wireless signal 48 between the controller 40 and the communication module 44. The wireless data communication transceiver 46 can be Bluetooth, WiFi, a wireless power antenna, or any type of wireless technology. The data can transfer through a CAN or LIN network. Data obtained from testing is shown on the display 42.

When the test is performed, the communication module 44 sends results and information about the test collected by the connector 34 to the controller 40. The information can be data relating to testing the seat memory function check, the occupant classification function check that is to ensure that the occupant weight reflects correctly, the power function to a cooling fan in the component, the function of the seat belt, and the seat heater. The controller 40 knows the type of seat and hence which tests to run or not run. The tests relating to the seat memory function check and the occupant classification function check that ensures that the occupant weight reflects correctly are high speed 2 way communication using CAN and LIN.

The controller 40 also sends a signal to the transmitter 22 of the wireless power system 20 through a wired line 50 to control the one-way transfer of a wireless power signal 28 from the transmitter 22 to the receiver 24. The communication module 44 is also powered by the receiver 24 through a wired line 52.

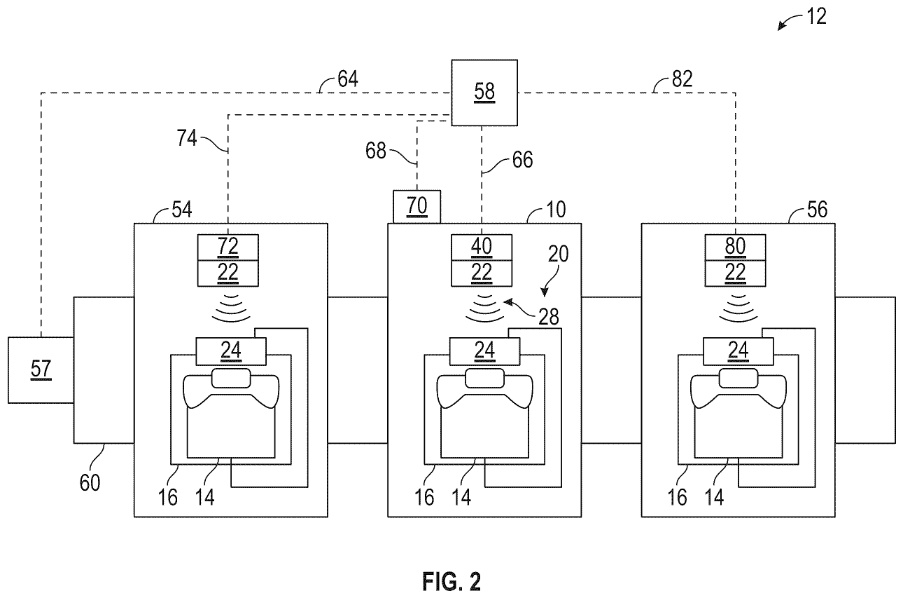

FIG. 2 shows the production line 12 including a connection station 54, the testing station 10, and a disconnection station 56. In one example, there are six testing stations 10 located between the connection station 54 and the disconnection station 56. Any test can be performed at each of the testing stations 10, including the tests mentioned above. At each testing station 10, the results of the test are shown on the display 42 of the controller 40 and communicated to a master computer 58. The pallet 16 with the attached component 14 moves along the production line 12 from station to station along a conveyor belt 60 that is moved by a motor 57.

After the component 14 is manufactured during production, the component 14 arrives at the connection station 54. At the connection station 54, the component 14 is connected to the pallet 16. A controller 72 at the connection station 54 communicates with the master computer 58 through a signal 74. The master computer 58 sends a signal 64 to the motor 57 to move the conveyor belt 60 and the pallet 16 with the attached component 14 from the connection station 54 to the testing station 10.

Each of the testing stations 10 includes a controller 40 and a sensor 70, and the sensor 70 detects the presence of the pallet 16 at each testing station 10. When the sensor 70 detects the pallet 16 at the testing station 10, a signal 68 is sent to the master computer 58, and the master computer 58 communicates with and sends a signal 64 to the motor 57 to stop the conveyor belt 60 to position the pallet 16 with the component 14 at the testing station 10 so the test can be performed.

The master computer 58 then sends a signal to the controller 40 to send a signal to the transmitter 22 to begin the transfer of wireless power to the receiver 24 for testing as described above. At the testing station 10, wireless power is transferred from the transmitter 22 associated with the assembly rail 18 to the receiver 24 associated with the pallet 16 to power the component 14 for testing. When wireless power is being transferred to the component 14, a light 76 on the transmitter 22 and a light 78 on the receiver 24 are illuminated (shown in FIG. 1).

Data obtained from the test of the component 14 performed at the testing station 10 is communicated from the connector 34 through the signal 84 to the communication module 44 and from the communication module 44 through the wireless signal 48 to the controller 40 to be displayed on the display 42 via the wireless data communication transceiver 46. Once the test is completed, the master computer 58 sends a signal to the transmitter 22 to stop the transmission of wireless power. This way, power is only wirelessly transferred when the pallet 16 is located at the testing station 10. The tests results are sent by the controller 40 to the master computer 58 to be registered by the manufacturing plant. Once the test is complete, the controller 40 sends a signal 66 with the test data to the master computer 58 as described above.

If the component 14 passes the test at the testing station 10, the master computer 58 sends a signal to the motor 57 to move the conveyor belt 60 so that the pallet 16 leaves the testing station 10 and moves to another testing station 10, where the process repeats. The pallet 16 continues to move to additional testing stations 10 repeating the above process until all the tests are complete at all the testing stations 10. The pallet 16 only leaves the testing station 10 to continue to the next testing station 10 if the component 14 passes the test at the previous testing station 10. If the component 14 does not pass the test at the testing station 10, the controller 40 sends a signal 66 to the master computer 58 to alert the manufacturing plant.

Once all the tests have been performed at all the testing stations 10, the pallet 16 moves to the disconnection station 56. A controller 80 at the connection station 54 communicates with the master computer 58 through a signal 82. At the disconnection station 56, the component 14 is disconnected from the pallet 16.

Any feature of the component 14 can be tested. For example, a quality of the component 14 can be tested or functions of the component 14 can be tested or checked. The following features or qualities can be tested: belt continuity, sound, memory, thermistor, heat current, fan current, occupant classification system, and noise level of a fan.

The foregoing description is only exemplary of the principles of the invention. Many modifications and variations of the present invention are possible in light of the above teachings. The preferred embodiments of this invention have been disclosed, however, so that one of ordinary skill in the art would recognize that certain modifications would come within the scope of this invention. It is, therefore, to be understood that within the scope of the appended claims, the invention may be practiced otherwise than as specifically described. For that reason the following claims should be studied to determine the true scope and content of this invention.

What is claimed is:

1. A wireless power system of a testing system, the wireless power system comprising:
a transmitter associated with an assembly rail; and
a receiver associated with a component, wherein the transmitter transfers wireless power to the receiver.

2. The wireless power system as recited in claim 1 including a pallet connected to the component, and the pallet moves relative to the assembly rail.

3. The wireless power system as recited in claim 1 including a power source that supplies power to the transmitter, and the transmitter sends a wireless power signal to the receiver to wirelessly power the component during a test.

4. The wireless power system as recited in claim 3 wherein one of electromagnetic resonance or induction is used to wirelessly transfer power from the transmitter to the receiver.

5. The wireless power system as recited in claim 1 wherein the receiver is connected to the pallet by a first attachment mechanism, and the transmitter is connected to the assembly rail by a second attachment mechanism.

6. The wireless power system as recited in claim 5 wherein the first attachment mechanism and the second attachment mechanism are each a threaded fastener or a screw.

7. The wireless power system as recited in claim 1 including a connector that connects the component to the receiver, wherein power travels from the receiver, through the connector, and to the component for testing.

8. The wireless power system as recited in claim 1 including a controller, a display associated with the controller, and a communication module, and data obtained during a test is wirelessly transferred through a two-way wireless signal between the communication module and the controller and shown on the display.

9. The wireless power system as recited in claim 8 wherein the communication module is associated with the pallet, and a wireless data communication transceiver located between the control and the communication module wirelessly transfers the data between the controller and the communication module.

10. The wireless power system as recited in claim 8 wherein the controller sends a signal to the transmitter through a wired line to control one-way transfer of wireless power from the transmitter to the receiver during testing.

11. The wireless power system as recited in claim 1 including a motor, a conveyor belt moved by the motor, a connection station, a testing station, and a disconnection station, and the pallet with the component attached to the pallet moves along the production line from the connection station, to the testing station, to the disconnection station along the conveyor belt.

12. The wireless power system as recited in claim 11 including a master computer, wherein the testing station comprises a plurality of testing stations each including a controller, a sensor, and a display, wherein when each of the sensors detect the pallet at one of the plurality of testing stations, a signal is sent to the master computer to send a signal to the motor to stop the conveyor belt so that a test can be performed, and the controller sends a signal to the transmitter to begin the transfer of wireless power to from the transmitter to the receiver to power the test.

13. The wireless power system as recited in claim 12 wherein data obtained from the test at the testing station is communicated to the master computer and the controller and shown on the display, and the master computer sends a signal to the transmitter to stop the transmission of wireless power to the receiver when the test is complete.

14. The wireless power system as recited in claim 11 wherein if the component passes the test, the master computer sends a signal to the motor to move the conveyor belt so that the pallet leaves the testing station.

15. The wireless power system as recited in claim 11 wherein once when testing is completed at the testing station, the master computer sends a signal to the motor to move the conveyor belt so that the pallet leaves the testing station and moves to the disconnection station where the component is disconnected from the pallet.
